(19) United States
(12) Patent Application Publication
(10) Pub. No.: US 2026/0357420 A1
(43) Pub. Date: Nov. 12, 2026

(54) CLEANING PROCESS OF CHEMICAL VAPOR DEPOSITION FURNACE AND FURANCE WITH CLEANING FUNCTION

(71) Applicants: ACM RESEARCH (SHANGHAI), INC., Shanghai (CN); ACM Research (Lingang), Inc., Shanghai (CN)

(72) Inventors: Jiayan Shi, Shanghai (CN); Dongcheng Zhou, Shanghai (CN); Xiaoyan Zhang, Shanghai (CN); Hui Wang, Shanghai (CN)

(73) Assignees: ACM RESEARCH (SHANGHAI), INC., Shanghai (CN); ACM Research (Lingang), Inc., Shanghai (CN)

(21) Appl. No.: 19/137,266

(22) PCT Filed: Dec. 1, 2023
(86) PCT No.: PCT/CN2023/135755

§ 371 Date: Jun. 9, 2025

(30) Foreign Application Priority Data
Dec. 9, 2022 (CN) 202211586915.6

(51) Int. Cl. C23C 16/44; B08B 5/00

(52) U.S. Cl. CPC C23C 16/4405; B08B 5/00

(57) ABSTRACT

A cleaning process includes the following steps: sealing a chamber with a layer to be cleaned inside, setting the environmental condition inside the chamber; introducing cleaning gas from the bottom of the chamber, cleaning the layer to be cleaned in the chamber. Setting the environmental condition inside the chamber includes: the temperature inside the chamber is controlled from bottom to top in a gradient from high to low. In the cleaning process, by increasing the temperature of the bottom of the chamber of the furnace, the thermal decomposition speed of the cleaning gas at the bottom of the chamber can be accelerated, so that the cleaning rate of the whole chamber tends to be consistent. Hence, the cleaning efficiency of the whole chamber can be increased.

### FIELD OF THE INVENTION

The present invention relates to the technical field of semiconductor manufacturing, in particular to a cleaning process of a chemical vapor deposition furnace and a furnace with a cleaning function.

### BACKGROUND

In the semiconductor manufacturing process, the maintenance and cleaning of machine is very important. In the chemical vapor deposition process, the reaction gas source silane enters a reaction chamber in a gaseous form. Under the action of high temperature, the silane decomposes to generate polysilicon, silicon nitride and other products that are deposited on the wafer in the reaction chamber. In this process, the products are not only deposited on the surface of the wafer, but also deposited anywhere in the chamber, such as each region of the inner chamber in the vertical furnace and on the inner side wall of the outer chamber and in the gap between the inner chamber and the outer chamber. In order to prevent the deposition of the products over a long period of time from affecting the quality of wafer processing, hence, it is necessary to periodically clean the reaction chamber. Cleaning gas is generally used as a cleaning agent in the art. The principle is to use the highly oxidizing product produced by high-temperature decomposition of the cleaning gas to react with the product to be removed in the chamber, so as to generate gas and be pumped away, thereby achieving the purpose of cleaning.

In the actual process, it is found that after the chamber of the furnace is cleaned for a certain number of times, the top of the chamber is damaged, resulting in a decrease in the yield rate of wafer processing. At present, in order to solve this problem, the selected treatment method is: after the chamber of the furnace is cleaned for a certain number of times, the chamber of the furnace can be replaced, but the maintenance cost, labor cost and material cost of this method are all large.

### SUMMARY

Therefore, the purpose of the present invention is to propose a cleaning process of a chemical vapor deposition furnace and a furnace with a cleaning function, which can reduce the damage degree of the top of the chamber, prolong the service life of the chamber of the furnace, and save labor cost, maintenance cost and material cost.

According to the first aspect, the present invention provides a cleaning process of a chemical vapor deposition furnace, comprising the following steps:
sealing a chamber with a layer to be cleaned inside, setting the environmental condition inside the chamber;
introducing cleaning gas from the bottom of the chamber, cleaning the layer to be cleaned in the chamber;
wherein, setting the environmental condition inside the chamber includes: the temperature inside the chamber is controlled from bottom to top in a gradient from high to low.

According to a specific implementation of the embodiment of the present application, the cleaning gas is fluorinated gas.

According to a specific implementation of the embodiment of the present application, setting the environmental condition inside the chamber further includes: setting the pressure inside the chamber to 0.1-1.2 torr.

According to a specific implementation of the embodiment of the present application, when the temperature inside the chamber is controlled from bottom to top in a gradient from high to low, the temperature at the bottom of the chamber is 15-30 °C higher than the temperature at the top of the chamber.

According to a specific implementation of the embodiment of the present application, the cleaning process further includes: after the layer to be cleaned in the chamber is cleaned, the cleaning gas is continuously introduced for a period of time, so that the layer to be cleaned is completely cleaned.

According to a specific implementation of the embodiment of the present application, after the layer to be cleaned in the chamber is cleaned, the time for continuously introducing the cleaning gas is 3-5 minutes.

According to a specific implementation of the embodiment of the present application, the cleaning process further includes: after the layer to be cleaned in the chamber is cleaned, inert gas or nitrogen gas is continuously introduced into the chamber for a period of time, so as to remove the by-product in the chamber.

According to a specific implementation of the embodiment of the present application, the flow rate of the inert gas or nitrogen gas introduced into the chamber is 1.5 SL-2 SL, and the continuous introduction time is 3-5 minutes.

According to the second aspect, the present invention provides a chemical vapor deposition furnace with a cleaning function, comprising:
at least two temperature control modules for heating a sealed chamber of the furnace;
a control module, configured to control the temperature control modules to adjust the environmental condition inside the chamber, and
controlling cleaning gas to be introduced to the chamber from the bottom of the chamber, so as to clean a layer to be cleaned in the chamber;
wherein, the environmental condition includes: the temperature inside the chamber is controlled from bottom to top in a gradient from high to low.

According to a specific implementation of the embodiment of the present application, each temperature control module includes at least one heating unit.

According to a specific implementation of the embodiment of the present application, the control module is further configured to control a pressure control module to adjust the environmental condition inside the chamber, and the environmental condition includes that the pressure inside the chamber is to be 0.1-1.2 torr.

The present invention provides a cleaning process of a chemical vapor deposition furnace and a furnace with a cleaning function, by increasing the temperature of the bottom of the chamber of the furnace, the thermal decomposition speed of the cleaning gas at the bottom of the chamber can be accelerated, so that the cleaning speed of the whole chamber tends to be consistent. This improves the cleaning efficiency of the whole chamber, shortens the cleaning time of the chamber, and also improves the problem of the damage caused by excessive cleaning of the top of the chamber due to the need to prolong the cleaning time of the bottom of the chamber. The present invention prolongs the service life of the chamber, guarantees the processing quality of the wafer, and reduces the labor cost, maintenance cost and material cost at the same time. Other features and advantages of the present invention will be set forth in the following specification, and, partly become apparent from the specification, or will be learned by practicing the present invention. The objects and other advantages of the present invention can be achieved and obtained by the structure pointed out in the specification and the accompanying drawings.

### BRIEF DESCRIPTION OF THE DRAWINGS

In order to more clearly explain the embodiments of the present invention or the technical solutions in the prior art, the drawings that need to be used in the description of the embodiments or the prior art will be briefly introduced below. It is obvious that the drawings in the following description are some embodiments of the present invention, and for those of ordinary skill in the art, other drawings can be obtained according to these drawings without making creative efforts.

FIG. 1 shows a schematic view of sectional structure of a furnace device;

FIG. 2 shows a schematic flow diagram of a cleaning process of a chemical vapor deposition furnace according to an embodiment of the present invention; and

FIG. 3 shows a schematic structural view of a chemical vapor deposition furnace with a cleaning function according to an embodiment of the present invention.

### PREFERRED EMBODIMENTS OF THE INVENTION

In order to make the objects, technical solutions and advantages of the embodiments of the present invention clearer, the technical solutions in the embodiments of the present invention will be clearly and completely described below with reference to the accompanying drawings in the embodiments of the present invention. It is obvious that the described embodiments are a part of the embodiments of the present invention, but not all the embodiments. Based on the embodiments in the present invention, all other embodiments obtained by those of ordinary skill in the art without making creative efforts belong to the scope of protection of the present invention.

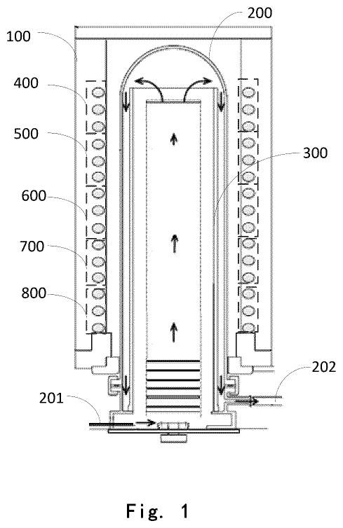

Before introducing a cleaning process of a chemical vapor deposition furnace of the present invention, the structure of a furnace device should be firstly understood. Please refer to FIG. 1. FIG. 1 shows a schematic view of sectional structure of a furnace device. As shown in FIG. 1, the furnace device comprises a furnace body 100 and a chamber, and the chamber comprises an outer chamber 200 and an inner chamber 300. The inner chamber 300 is vertically arranged inside the furnace body 100, and the outer chamber 200 is sleeved outside the inner chamber 300. The outer chamber 200 is also vertically arranged inside the furnace body 100, and a gap is formed between the inner chamber 300 and the outer chamber 200, wherein the top of the outer chamber 200 is sealed in arrangement. The actual structure of the inner chamber 300 is a tubular structure, and the internal space of the outer chamber 200 and the inner chamber 300 together constitute a chamber. A temperature control region is provided on the side wall of the furnace body 100. Because the structural size of the furnace device is very large, in the process of heating the chamber in the temperature control region, it is easy to appear that the temperature in some regions is too high and the temperature in some regions is too low, resulting in uneven conditions. However, when the wafer is subjected to the chemical vapor deposition, the high requirements are set to the temperature accuracy and uniformity. In the production and manufacturing process, in order to control the temperature of each region of the chamber uniform, so that the whole temperature of the chamber can be more precisely controlled to be consistent, the temperature control region is generally divided into five heating units, namely, the first heating unit 400, the second heating unit 500, the third heating unit 600, the fourth heating unit 700 and the fifth heating unit 800, respectively. During the process, by controlling a plurality of heating units to heat the furnace to the same target temperature at the same time, the temperature inside the chamber of the furnace is further controlled to achieve better uniformity. Specifically, each heating unit comprises a heater, a temperature sensor and a controller. During the heating process, the controller controls the heater to heat the chamber. At the same time, the temperature sensor monitors the temperature inside the chamber and transmits the monitored temperature data information to the controller in real time. Once monitoring the temperature inside the chamber reaches the preset target temperature, the controller immediately controls the heater to stop heating.

When it is necessary to clean the chamber of the furnace after the chemical vapor deposition process of the wafer is completed, considering that it is necessary to cooperate with the structural characteristics of the existing chamber of the furnace, the general method is: By controlling a plurality of heating units to uniformly heat the chamber at the same temperature, then the cleaning gas is introduced into the inner chamber 300 from a gas inlet 201 at the bottom of the outer chamber 200 of the furnace device and reaches the top of the inner chamber 300, then passes through the gap between the inner chamber 300 and the outer chamber 200, and finally is pumped away from a gas outlet 202 at the bottom of the outer chamber 200. The cleaning gas is generally selected according to the layer to be cleaned. However, the inventors of the present application have found that after a certain number of cleanings, the yield rate of wafer processing decreases. After analysis by the inventors of the present application, it is found that after the chamber of the furnace is cleaned a certain number of times, the top portion can be excessively cleaned, and the particles can be generated, which will affect the wafer processing during the process of wafer processing. At present, in order to avoid the decline of wafer yield due to the above reason, the selected treatment method is: After the chamber of the furnace is cleaned for a certain number of times, the chamber of the furnace can be replaced, but the maintenance cost, labor cost and material cost of this method are all relatively large. Therefore, the inventors of the present invention have studied the above situation and proposes a cleaning process of a chemical vapor deposition furnace, which can reduce the damage degree of the top of the chamber, prolong the service life of the chamber of the furnace, and save the labor cost, maintenance cost and material cost.

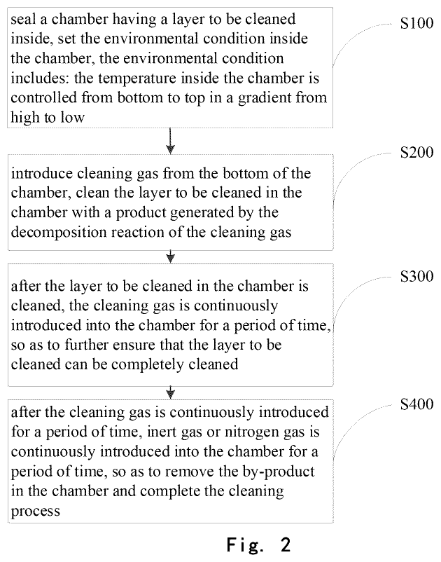

Please refer to FIG. 2, which shows a schematic flow diagram of a cleaning process of a chemical vapor deposition furnace according to an embodiment of the present invention. As shown in FIG. 2, the cleaning process of the chemical vapor deposition furnace of the present invention comprises the following steps:

Step S100: seal the chamber having the layer to be cleaned inside, set the environmental condition inside the chamber.

Specifically, at the time of sealing, as shown in FIG. 1, the outer chamber 200 is sleeved outside the inner chamber 300, so that the inside of the chamber is the sealed environment. The layer to be cleaned is a product deposited on other regions other than the wafer surface in the process of chemical vapor deposition. The other regions in the embodiment of the present invention include each region of the inner chamber 300, on the inner side wall of the outer chamber 200 and in the gap between the inner chamber 300 and the outer chamber 200. Setting the environmental condition inside the chamber includes: the temperature inside the chamber is controlled from bottom to top in a gradient from high to low.

When the cleaning gas enters the bottom of the inner chamber 300, the reaction temperature can't be reached due to the low temperature. Therefore, when the cleaning gas enters the inner chamber 300 in the beginning, the cleaning gas is not immediately cleaned. The cleaning gas is continuously heated during the upward circulation process, and a partial thermal decomposition reaction will occur during the heating process. However, the reaction occurring during the cleaning process is exothermic, which will cause the temperature of the gas at the top of the inner chamber 300 to be significantly higher than the temperature of the gas at the bottom of the inner chamber 300. During the cleaning process, the cleaning gas, such as the chlorine trifluoride, can preferentially and completely decompose at the top of the inner chamber 300 and the upper part of the outer chamber 200 and generate sufficient fluorine gas to firstly react with the layer to be cleaned in the chamber of the furnace, and gradually extend towards the bottom of the chamber. This easily causes the cleaning of the top of the chamber to begin first and clean first, and the bottom of the chamber to be cleaned after the top of the chamber is cleaned for a period of time. As a result, the top of the chamber has been cleaned, but the bottom of the chamber has not been cleaned. Therefore, in order to ensure that the bottom of the inner chamber 300 and the outer chamber 200 can also be cleaned, the cleaning time of the whole cleaning program can only be prolonged. As a result, it is inevitable that the top of the chamber can be damaged due to the excessive cleaning. When the number of cleanings is enough, the impact of damage to the top of the chamber will be highlighted, and the result of the impact is a decrease in the yield rate of wafer processing.

Therefore, in the actual cleaning process of the embodiment of the present invention, different cleaning gases are selected according to different products produced by different chemical vapor deposition processes. Then, according to the actual reaction temperature of the cleaning gas, a plurality of heating units in the temperature control region of the furnace body are divided into regions, and then the heating temperature of each region of the furnace body can be selected and set. When setting, the temperature control region of the furnace body is divided into regions, including the control of the temperature inside the chamber from bottom to top in a gradient from high to low.

For example, in combination with the structure of the furnace device, the temperature control region of the furnace body is divided into regions, and when the temperature control region is divided into the bottom, middle and top, the bottom is the fourth heating unit 700 and the fifth heating unit 800, the middle is the second heating unit 500 and the third heating unit 600, and the top is the first heating unit 400. The specific setting method is: The temperature at the bottom of the chamber is 10-20 °C higher than the temperature at the middle of the chamber, and the temperature at the middle of the chamber is 5-10 °C higher than the temperature at the top of the chamber. Inside the bottom, the temperature stays consistent, and the temperature inside the middle and top also stays consistent.

In another embodiment, in combination with the structure of the furnace device, the temperature control region of the furnace body is divided into regions, and when the temperature control region is divided into the bottom and top, the bottom is the fourth heating unit 700 and the fifth heating unit 800, and the top is the first heating unit 400, the second heating unit 500 and the third heating unit 600. The specific setting method is: The temperature at the bottom of the chamber is 15-30 °C higher than the temperature at the top of the chamber. Inside the bottom and top, the temperature stays consistent.

Furthermore, setting the environmental condition inside the chamber further includes: setting the pressure inside the chamber to be 0.1-1.2 torr.

Step S200: introduce the cleaning gas from the bottom of the chamber, clean the layer to be cleaned in the chamber with a product generated by the decomposition reaction of the cleaning gas, for example, the product is the fluorine gas.

Furthermore, the flow rate of the cleaning gas introduced into the chamber is 1.5 SL-2 SL.

Preferably, the cleaning process further includes the step S300: After the layer to be cleaned in the chamber is cleaned, the cleaning gas is continuously introduced into the chamber for a period of time, so as to further ensure that the layer to be cleaned can be completely cleaned. For example, in the embodiment of the present invention, the cleaning gas is continuously introduced for 3-5 minutes, and the flow rate can be kept constant. It is worth noting that when the layer to be cleaned in the chamber is cleaned, the time required to be cleaned can be determined by experience, and the time to reach the cleaning can be directly determined to be cleaned. The temperature sensor in the heating units can also monitor the temperature change in the chamber in real time for determination. When the cleaning gas is continuously introduced and the temperature monitored by the temperature sensor is consistent with the temperature controlled by the temperature control region, that is, when the detected temperature is equal to the temperature heated by the heating units in the temperature control region, it can be determined that the cleaning is cleaned. The reason why the above situation can be determined is that the reaction that occurs when the cleaning gas cleans the layer to be cleaned is an exothermic reaction, and the specific reaction that occurs will be described in detail below. As long as the layer to be cleaned is not cleaned, the cleaning gas will continue to react with the layer to be cleaned. The temperature inside the chamber detected by the temperature sensor will continue to be higher than the temperature heated by the heating units in the temperature control region, until the temperature inside the chamber detected by the temperature sensor is equal to the temperature heated by the heating units in the temperature control region, indicating that the cleaning reaction does not occur again, and the layer to be cleaned can be completely cleaned.

Preferably, the cleaning process further includes the step S400: After the cleaning gas is continuously introduced for a period of time, the inert gas or nitrogen gas is continuously introduced into the chamber for a period of time, so as to remove the by-product in the chamber and complete the cleaning process. For example, in the embodiment of the present invention, the nitrogen gas is selected. Furthermore, in the embodiment of the present invention, the flow rate of the nitrogen gas introduced into the chamber is 1.5 SL-2 SL, and the continuous introducing time is 3-5 minutes.

In the art, the fluorinated gas is commonly selected as the cleaning gas for the chemical vapor deposition product, wherein, the chlorine trifluoride can be particularly and commonly used. The chlorine trifluoride is relatively stable at the normal temperature, and the activity of chlorine trifluoride is similar to the activity of chlorine gas. However, the activity of chlorine trifluoride increases rapidly when heated, and begins to decompose at the temperature of 250 °C, and the products are chlorine fluoride and fluorine gas. The reaction releases a lot of heat, and the heat generated further exacerbates the decomposition of chlorine trifluoride, resulting in generating more fluorine gas. When the temperature reaches 600 °C, the chlorine trifluoride can be completely decomposed. The fluorine gas produced by the reaction can react with chemical vapor deposition products such as the polycrystalline silicon, silicon nitride, silicon carbon nitrogen, and the like in the chamber, so as to generate the silicon tetrafluoride gas and be pumped away, thereby achieving the purpose of cleaning.

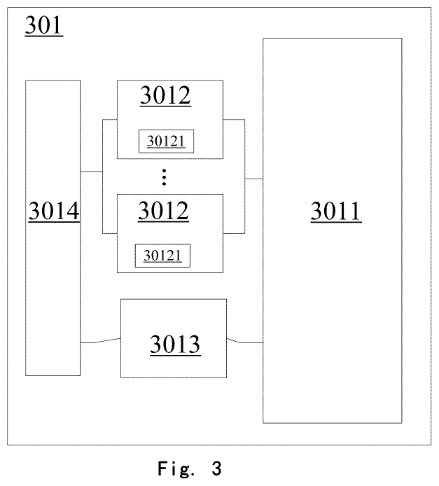

The embodiment of the present invention provides a chemical vapor deposition furnace with a cleaning function to match the implementation of the cleaning process of the chemical vapor deposition furnace described above. Please refer to FIG. 3, which shows a schematic structural view of a chemical vapor deposition furnace with a cleaning function according to an embodiment of the present invention. As shown in FIG. 3, the chemical vapor deposition furnace 301 with the cleaning function comprises:
at least two temperature control modules 3012 for heating the sealed chamber 3011 of the furnace;
a control module 3014, configured to control the temperature control modules 3012 to adjust the environmental condition inside the chamber 3011, and,
controlling the cleaning gas to be introduced to the chamber 3011 from the bottom of the chamber 3011, so as to clean the layer to be cleaned in the chamber 3011;
wherein, the environmental condition includes: the temperature inside the chamber 3011 is controlled from bottom to top in a gradient from high to low.

Furthermore, each temperature control module 3012 includes at least one heating unit 30121.

Furthermore, the control module 3014 is further configured to control the pressure control module 3013 to adjust the environmental condition inside the chamber 3011; the environmental condition herein specifically includes: the pressure inside the chamber 3011 is to be 0.1-1.2 torr.

Next, an exemplary explanation of the cleaning process of the chemical vapor deposition furnace according to an embodiment of the present invention will be described as an actual case of cleaning the chamber having the polycrystalline silicon thin film by using the chlorine trifluoride gas as the cleaning gas.

Please refer to FIG. 1, the embodiment of the present invention provides a chamber having a polycrystalline silicon thin film inside, and the whole chamber is sealed. In the present embodiment, the furnace body is provided with five heating units, which are respectively divided into a first heating unit 400, a second heating unit 500, a third heating unit 600, a fourth heating unit 700 and a fifth heating unit 800 from top to bottom. After the five heating units are divided into regions, both the accurate heating and temperature control can be carried out in each region, so as to realize different temperature control in different regions of the chamber. The environmental condition inside the chamber can be established, including the temperature condition and the pressure condition. The temperature inside the chamber is controlled from bottom to top in a gradient from high to low. In the embodiment of the present invention, the temperature control region of the furnace body is divided into regions, and the temperature control region is divided into the bottom, middle and top. Specifically, the bottom is the fourth heating unit 700 and the fifth heating unit 800, the middle is the second heating unit 500 and the third heating unit 600, and the top is the first heating unit 400. The temperature conditions are specifically set as follows: The temperature of the bottom of the chamber is set to 400 °C, that is, the temperatures of the fourth heating unit 700 and the fifth heating unit 800 are set to 400 °C; And the temperature at the bottom of the chamber is 15 °C higher than the temperature at the middle of the chamber, that is, the temperatures of the second heating unit 500 and the third heating unit 600 are set to 385 °C; The temperature in the middle of the chamber is 15 °C higher than the temperature at the top of the chamber, that is, the temperature of the first heating unit 400 is set to 370 °C. In the embodiment of the present invention, the pressure condition inside the chamber is set to 1.0 torr.

The chlorine trifluoride is introduced into the inner chamber 300 from the gas inlet 201 provided at the bottom of the outer chamber 200, and the flow rate is set to 1.75 SL. The polycrystalline silicon in the chamber can be cleaned by the fluorine gas generated by the decomposition reaction of chlorine trifluoride. The introduced chlorine trifluoride gas undergoes decomposition reaction under the condition of being heated and high temperature, so as to generate the chlorine fluoride and fluorine gas, and then the generated fluorine gas is used to clean the polycrystalline silicon layer in the chamber. The cleaning in the embodiment of the present invention refers to using the reaction of fluorine gas and silicon to remove the polycrystalline silicon layer in the chamber, and the reaction equation of the decomposition of chlorine trifluoride to generate the fluorine gas and chlorine fluoride to remove the polycrystalline silicon is that: ClF3→ClF+F2; Si+F2→SiF4, and the product SiF4 is present in a gaseous state in the chamber. In the present invention, the fluorinated gas is introduced into the chamber, and the polycrystalline silicon layer in the chamber is cleaned by the fluorine gas, until the polycrystalline silicon layer in the chamber can be completely cleaned.

After cleaning, the nitrogen is continuously filled for a period of time, so as to remove the by-product in the chamber and complete the cleaning process. In the embodiment of the present invention, a gas extraction device (not shown in the drawing) is provided at the gas outlet 202, so as to pump away the by-product in the chamber from the gap between the inner chamber 300 and the outer chamber 200 through the gas outlet 202. Since the chlorine trifluoride gas introduced from the bottom of the chamber is decomposed to produce the fluorine gas and chlorine fluoride, and the fluorine gas further reacts with the silicon to produce the silicon tetrafluoride gas, so that the main components of the by-product after the reaction are silicon tetrafluoride and chlorine fluoride. In order to ensure a sufficient reaction, clean the poly crystalline silicon layer inside the furnace. After cleaning, continue to fill the chlorine trifluoride gas for 3-5 minutes, so as to further ensure that the polycrystalline silicon film layer can be completely cleaned and ensure the cleaning effect. The nitrogen gas is then filled for 3-5 minutes to facilitate pumping away the by-product.

By carrying out the regional heating of the furnace, the present invention realizes a precise control of different temperatures in different regions, makes the cleaning efficiency of the whole chamber tends to be consistent, improves the problem of the damage caused by excessive cleaning of the top of the chamber due to the need to prolong the time for cleaning the chamber because of the initial temperature not up to standard. The service life of the chamber can be prolonged, the processing quality of wafer can be guaranteed, and at the same time, the cost can be reduced.

Furthermore, by increasing the temperature of the bottom of the chamber of the furnace, the cleaning gas at the bottom of the chamber can be promoted to quickly reach the reaction temperature, and the decomposition speed of the cleaning gas can be improved, thereby improving the cleaning efficiency of the chamber. Taking the thickness of the polysilicon thin layer in the chamber as 10 microns as an example, the adopted time required by the existing cleaning process is about 130 minutes, while the adopted time required by the cleaning process of the present invention is about 115 minutes.

Although the present invention has been described in detail with reference to the aforementioned embodiments, those of ordinary skill in the art should understand that the technical solutions described in the aforementioned embodiments may still be modified or some technical features may be equivalently replaced. However, these modifications or substitutions do not deviate the essence of the corresponding technical solutions from the spirit and scope of the technical solutions of each embodiment of the present invention.

1. A cleaning process of a chemical vapor deposition furnace, comprising the following steps:
sealing a chamber with a layer to be cleaned inside, setting the environmental condition inside the chamber;
introducing cleaning gas from the bottom of the chamber, cleaning the layer to be cleaned in the chamber;
wherein, setting the environmental condition inside the chamber includes: the temperature inside the chamber is controlled from bottom to top in a gradient from high to low.

2. The cleaning process of the chemical vapor deposition furnace according to claim 1, wherein the cleaning gas is fluorinated gas.

3. The cleaning process of the chemical vapor deposition furnace according to claim 1, wherein setting the environmental condition inside the chamber further comprises:
the pressure inside the chamber is set to 0.1-1.2 torr.

4. The cleaning process of the chemical vapor deposition furnace according to claim 1, wherein when the temperature inside the chamber is controlled from bottom to top in a gradient from high to low, the temperature at the bottom of the chamber is 15-30 °C higher than the temperature at the top of the chamber.

5. The cleaning process of the chemical vapor deposition furnace according to claim 1, wherein the cleaning process further comprises:
after the layer to be cleaned in the chamber is cleaned, the cleaning gas is continuously introduced for a period of time, so that the layer to be cleaned is completely cleaned.

6. The cleaning process of the chemical vapor deposition furnace according to claim 5, wherein after the layer to be cleaned in the chamber is cleaned, the time for continuously introducing the cleaning gas is 3-5 minutes.

7. The cleaning process of the chemical vapor deposition furnace according to claim 1, wherein the cleaning process further comprises:
after the layer to be cleaned in the chamber is cleaned, inert gas or nitrogen gas is continuously introduced into the chamber for a period of time, so as to remove the by-product in the chamber.

8. The cleaning process of the chemical vapor deposition furnace according to claim 7, wherein the flow rate of the inert gas or nitrogen gas introduced into the chamber is 1.5 SL-2 SL, and the continuous introducing time is 3-5 minutes.

9. A chemical vapor deposition furnace with a cleaning function, comprising:
at least two temperature control modules for heating a sealed chamber of the furnace;
a control module, configured to control the temperature control modules to adjust the environmental condition inside the chamber, and
controlling cleaning gas to be introduced to the chamber from the bottom of the chamber, so as to clean a layer to be cleaned in the chamber;
wherein, the environmental condition includes: the temperature inside the chamber is controlled from bottom to top in a gradient from high to low.

10. The chemical vapor deposition furnace with the cleaning function according to claim 9, wherein:
each temperature control module comprises at least one heating unit.

11. The chemical vapor deposition furnace with the cleaning function according to claim 9, wherein:
the control module is further configured to control the pressure control module to adjust the environmental condition inside the chamber;
the environmental condition includes: the pressure inside the chamber is to be 0.1-1.2 torr.

12. The cleaning process of the chemical vapor deposition furnace according to claim 5, wherein the cleaning process further comprises:
after the layer to be cleaned in the chamber is cleaned, inert gas or nitrogen gas is continuously introduced into the chamber for a period of time, so as to remove the by-product in the chamber.

13. The cleaning process of the chemical vapor deposition furnace according to claim 12, wherein the flow rate of the inert gas or nitrogen gas introduced into the chamber is 1.5 SL-2 SL, and the continuous introducing time is 3-5 minutes.
